(19) United States
(12) Patent Application Publication
(10) Pub. No.: US 2026/0025936 A1
(43) Pub. Date: Jan. 22, 2026

(54) DISPLAY MODULE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Shaopeng Li, Beijing (CN); Hao Deng, Beijing (CN); Wenze Li, Beijing (CN); Weiben Zhang, Beijing (CN); Rongkun Fan, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/996,285

(22) PCT Filed: May 23, 2024
(86) PCT No.: PCT/CN2024/094837

§ 371 Date: Jan. 17, 2025

(30) Foreign Application Priority Data
May 25, 2023 (CN) 202310603509.4

(51) Int. Cl. H05K 5/02

(52) U.S. Cl. CPC H05K 5/0247

(57) ABSTRACT

A display module is provided, including a display panel, a flexible circuit board and a printed circuit board, wherein the flexible circuit board is connected to an end of the display panel along a first direction, and the flexible circuit board is bent to the backlight side of the display panel to be bound and connected with the printed circuit board, the flexible circuit board includes a first binding area for binding and connecting with the printed circuit board, and a first area adjacent to the first binding area in the first direction, the orthographic projection of the first area in a second direction is located on the printed circuit board, and the second direction is a direction perpendicular to the light emitting surface of the display panel. The present disclosure also relates to a display device.

### CROSS REFERENCE OF RELATED APPLICATION

The present disclosure claims a priority of Chinese patent disclosure No. 202310603509.4 filed on May 25, 2023, which is incorporated herein by reference in its entirety.

### TECHNICAL FIELD

The present disclosure relates to the technical field of OLED product manufacturing, and in particular to a display module and a display device.

### BACKGROUND

At present, customers of large-size vehicle-mounted/PAD/NB products have explicitly requested more assembly space to support large-capacity batteries to improve battery life, or to meet other special design requirements for assembly space.

One of the existing solutions is to reduce the Y-dimension of the FPC (flexible circuit board) or PCB (printed circuit board) to reduce the frame and achieve long battery life. However, this will bring other problems:

The Y-dimension of FPC or PCB is reduced, and the multi-layer board structure has uneven temperature distribution and poor uniformity, resulting in defects such as bonding miss/weak pressure, and the multi-layer board structure has a higher cost;

The Y-dimension of FPC or PCB is reduced, and a multi-layer board design is required. This will increase the thickness of FPC or PCB, which will cause PNL (panel) warping after bonding;

The components arranged on the surface of FPC/PCB require a certain amount of arrangement space, so there is a limit to the Y-direction size of FPC or PCB.

### SUMMARY

In order to solve the above technical problems, the present disclosure provides a display module and a display device to solve the problems of small Y-axis size and limited assembly space.

In order to achieve the above-mentioned purpose, a technical solution adopted in an embodiment of the present disclosure is: a display module, comprising a display panel, a flexible circuit board and a printed circuit board, wherein along a first direction, the flexible circuit board is connected to an end of the display panel, and the flexible circuit board is bent to the backlight side of the display panel to be bound and connected with the printed circuit board,
the flexible circuit board includes a first binding area for binding and connecting with the printed circuit board, and a first area adjacent to the first binding area in the first direction, the orthographic projection of the first area in the second direction is located on the printed circuit board, and the second direction is a direction perpendicular to the light emitting surface of the display panel.

In one example, the first binding area is located at an end of the flexible circuit board away from the display panel, and the first area is located at a side of the first binding area close to the display panel.

In one example, a second binding area for binding and connecting with the first binding area is provided on the printed circuit board, and in the first direction, the second binding area is located in the middle of the printed circuit board.

In one example, a second binding area for binding and connecting with the first binding area is provided on the printed circuit board. In the first direction, the second binding area is located at an end of the printed circuit board away from an end of the flexible circuit board.

In one example, the first binding area is located in the middle of the flexible circuit board, and the first area is located on a side of the first binding area close to the display panel.

In one example, a second binding area for binding and connecting with the first binding area is provided on the printed circuit board, and the second binding area is located at an end of the printed circuit board away from an end of the flexible circuit board.

In one example, in the first direction, the first binding area is located in the middle of the flexible circuit board, and in the first direction. the first area includes a first sub-area located on a side of the first binding area close to the display panel, and a second sub-area located on a side of the first binding area away from the display panel.

In one example, a second binding area for binding and connecting with the first binding area is provided on the printed circuit board, and in the first direction, the second binding area is located in the middle of the printed circuit board.

In one example, in the first direction, a gap between the printed wiring board and the display panel is less than or equal to 1 mm.

In one example, at least one of the flexible circuit board and the printed circuit board is a multi-layer board structure.

In one example, the printed circuit board is a multilayer board structure, and the printed circuit board includes a main body area and a second binding area located on one side of the main body area; or, the printed circuit board includes a main body area, and along the first direction, a hole is dug in the middle of the main body area to expose the corresponding metal conductive layer to form a second binding area, and the second binding area is configured to bind and connect with the first binding area.

In one example, the second binding region includes a conductive pin and a green oil layer located on a side of the conductive pin close to the main region.

In one example, the printed circuit board includes a component setting area, a lead setting area, and a second binding area. wherein the second binding area is used for binding and connecting with the first binding area, and the lead setting area is provided with leads for signal connection between the components in the component setting area and the second binding area;

The component setting area adopts a multi-layer board structure, and the lead setting area and the second binding area are single-layer board structures.

The embodiment of the present disclosure further provides a display device, comprising the above-mentioned display module.

The beneficial effect of the present disclosure is that: by setting the first area, the overlapping area of the flexible circuit board and the printed circuit board is increased, thereby shortening the total length of the flexible circuit board and the printed circuit board after binding connection in the first direction, which can further achieve a narrow frame and increase the assembly space of the power supply.

### BRIEF DESCRIPTION OF THE DRAWINGS

FIG. 1 is a schematic diagram showing the structure of a display module in the related art;

FIG. 2 is a first structural diagram of a display module in an embodiment of the present disclosure;

FIG. 3 is a second structural diagram of a display module in an embodiment of the present disclosure;

FIG. 4 is a third structural diagram of a display module in an embodiment of the present disclosure;

FIG. 5 is a fourth structural diagram of a display module in an embodiment of the present disclosure;

FIG. 6 is a fifth structural diagram of a display module in an embodiment of the present disclosure;

FIG. 7 is a sixth structural diagram of a display module in an embodiment of the present disclosure;

FIG. 8 is a first structural diagram of a printed circuit board in an embodiment of the present disclosure;

FIG. 9 is a second structural diagram of a printed circuit board in an embodiment of the present disclosure;

FIG. 10 is a third structural diagram of a printed circuit board in an embodiment of the present disclosure;

FIG. 11 is a fourth structural diagram of a printed circuit board in an embodiment of the present disclosure;

FIG. 12 is a fifth structural diagram of a printed circuit board in an embodiment of the present disclosure; and

FIG. 13 shows a sixth structural diagram of a printed circuit board in an embodiment of the present disclosure.

### DETAILED DESCRIPTION

In order to make the purpose, technical solution and advantages of the embodiments of the present disclosure clearer, the technical solution of the embodiments of the present disclosure will be clearly and completely described below in conjunction with the drawings of the embodiments of the present disclosure. Obviously, the described embodiments are part of the embodiments of the present disclosure, not all of the embodiments. Based on the described embodiments of the present disclosure, all other embodiments obtained by ordinary technicians in this field without creative work are within the scope of protection of the present disclosure.

Unless otherwise defined, the technical terms or scientific terms used in the present disclosure should be understood by people with ordinary skills in the field to which the present disclosure belongs. The “first”, “second” and similar words used in the present disclosure do not indicate any order, quantity or importance, but are only configured to distinguish different components. Similarly, similar words such as “one”, “one” or “the” do not indicate quantity restrictions, but indicate that there is at least one. Similar words such as “include” or “comprise” mean that the elements or objects appearing before the word cover the elements or objects listed after the word and their equivalents, without excluding other elements or objects. Similar words such as “connect” or “connected” are not limited to physical or mechanical connections, but can include electrical connections, whether direct or indirect. “Up”, “down”, “left”, “right” and the like are only configured to indicate relative positional relationships. When the absolute position of the described object changes, the relative positional relationship may also change accordingly.

Referring to FIGS. 2 to 12, this embodiment provides a display module, including a display panel 1, a flexible circuit board 2, and a printed circuit board 3. Along a first direction (refer to the X direction in FIG. 2), the flexible circuit board 2 is connected to an end of the display panel 1, and the flexible circuit board 2 is bent to the backlight side of the display panel 1 to be bound and connected to the printed circuit board 3.

The flexible circuit board 2 includes a first binding area 21 for binding and connecting with the printed circuit board 3, and a first area 22 adjacent to the first binding area 21 in the first direction, and the orthographic projection of the first area 22 in the second direction is located on the printed circuit board 3, and the second direction is a direction perpendicular to the light emitting surface of the display panel 1.

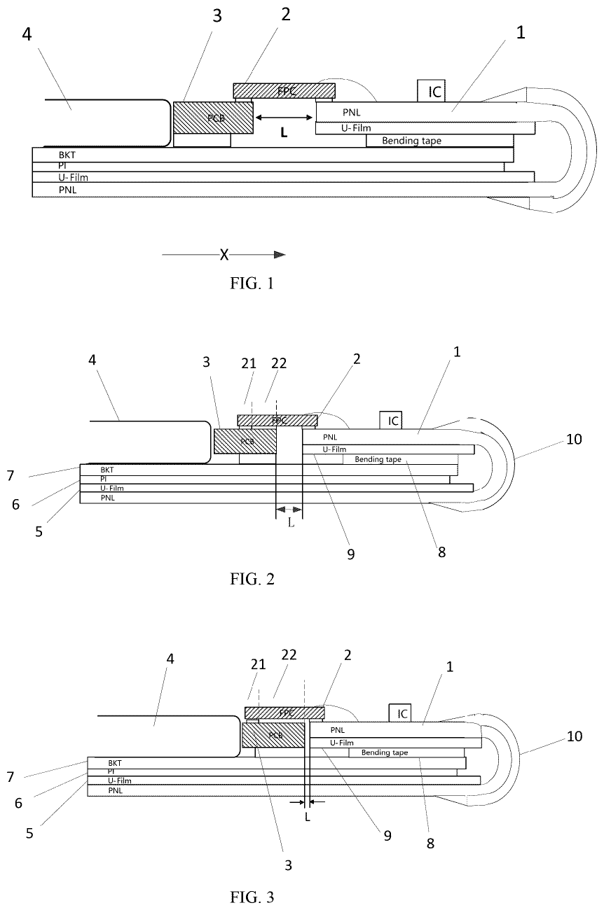

Referring to FIG. 1, in the conventional technology, the first binding area 21 of the flexible circuit board 2 is arranged at the edge of the side of the flexible circuit board 2 away from the display panel 1 (i.e., the distal end), and the second binding area 31 of the printed circuit board 3 is located at the edge of the side of the printed circuit board 3 close to the flexible circuit board 2 (i.e., the proximal end), that is, the distal end of the flexible circuit board 2 and the proximal end of the printed circuit board 3 are bound and connected, so that in the first direction, the total length of the flexible circuit board 2 and the printed circuit board 3 after being bound and connected is: (the length of the flexible circuit board 2−the length of the first binding area 21)+the length of the printed circuit board 3, therefore, the size of the display module in the first direction is limited by the size of the flexible circuit board 2 and the size of the printed circuit board 3, and the length L of the gap between the printed circuit board 3 and the display panel 1 in the first direction is limited and cannot be further reduced.

Referring to FIG. 1, the flexible circuit board 2 and the printed circuit board 3 are bound in a conventional manner, and the overlapping area of the flexible circuit board 2 and the printed circuit board 3 only includes a binding area for binding the flexible circuit board 2 and the printed circuit board 3. Referring to FIG. 2-FIG. 7. in this embodiment, the position of the binding area of the flexible circuit board 2 and/or the printed circuit board 3 is changed, so that the overlapping area of the flexible circuit board 2 and the printed circuit board 3 includes an area outside the first binding area 21 and the second binding area 31, that is, the overlapping area of the flexible circuit board 2 and the printed circuit board 3 is increased, thereby shortening the total length of the flexible circuit board 2 and the printed circuit board 3 after binding in the first direction, thereby breaking the limitation of the size of the flexible circuit board 2 and the printed circuit board 3 on the size of the display module in the first direction, and further realizing a narrow frame. L in FIG. 2-FIG. 5 is compared with L in FIG. 1. Obviously, in the structures of FIG. 2-FIG. 5, the length L of the printed circuit board 3 and the display panel 1 in the first direction is reduced, so that the assembly space of the power supply 4 in the first direction can also be increased.

It should be noted that, in the first direction, there is a tolerance setting for the length of the first binding area 21 and the length of the second binding area 31, that is, there is a situation where the orthographic projection of part of the first binding area 21 on the printed circuit board 3 is located outside the second binding area 31, or there is a situation where the orthographic projection of part of the second binding area 31 on the flexible circuit board 2 is located outside the first binding area 21. Therefore, in order to effectively reduce the total length of the flexible circuit board 2 and the printed circuit board 3 after the binding connection, at least part of the first area 22 is located in the area outside the second binding area 31.

There are many specific structural forms of the flexible circuit board 2 and the printed circuit board 3, as long as the first area 22 can be realized to shorten the total length of the flexible circuit board 2 and the printed circuit board 3 after binding connection in the first direction. The following introduces several binding connection methods adopted by the flexible circuit board 2 and the printed circuit board 3 in this embodiment.

Referring to FIGS. 2, 3, 6 and 7, in an exemplary embodiment, the first binding area 21 is located at an end of the flexible circuit board 2 away from the display panel 1, and the first area 22 is located on a side of the first binding area 21 close to the display panel 1.

Relative to FIG. 1, the position of the first binding area 21 remains unchanged, but the second binding area 31 moves in the direction away from the display panel 1, so that the first area 22 is formed on the side of the first binding area 21 close to the display panel 1. Compared with FIG. 1, the formation of the first area 22 increases the overlapping area between the flexible circuit board 2 and the printed circuit board 3, shortens the total length of the flexible circuit board 2 and the printed circuit board after binding and connection in the first direction, and increases the assembly space of the power supply.

FIG. 2 is a schematic diagram showing a flexible circuit board in a bent state, and FIG. 6 is a schematic diagram showing a flexible circuit board in an unfolded state.

Referring to FIGS. 2 and 6, illustratively, a second binding area 31 for binding and connecting with the first binding area 21 is provided on the printed circuit board 3, and in the first direction, the second binding area 31 is located in the middle of the printed circuit board 3.

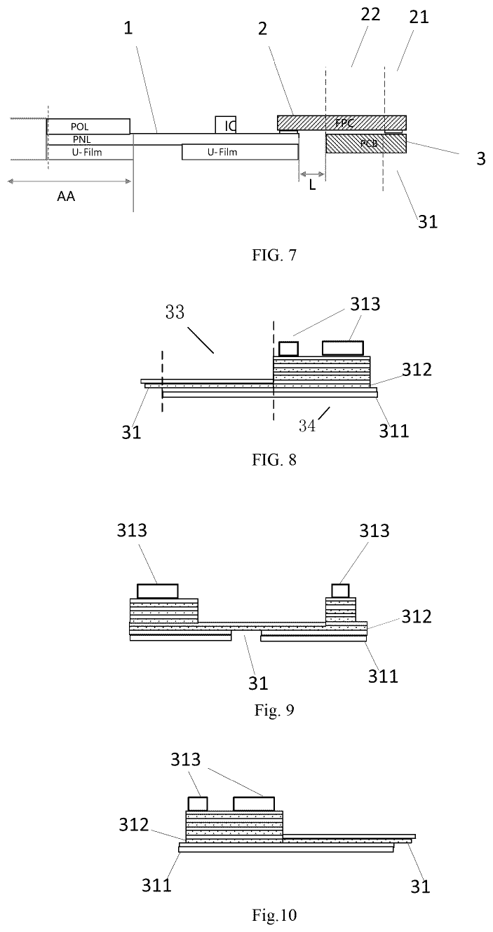

FIG. 3 is a schematic diagram showing a flexible circuit board in a bent state, and FIG. 7 is a schematic diagram showing a flexible circuit board in an unfolded state.

Referring to FIGS. 3 and 7, exemplarily, the printed circuit board 3 is provided with a second binding area 31 for binding and connecting with the first binding area 21, and in the first direction, the second binding area 31 is located at an end of the printed circuit board 3 away from an end of the flexible circuit board 2.

It should be noted that the position of the second binding area 31 is not limited to that described above. As long as the second binding area 31 is located at the edge of the printed circuit board 3 close to the display panel 1 relative to that shown in FIG. 1, the second binding area 31 is moved a certain distance away from the display panel 1, so that the first area 22 is formed on the side of the second binding area 31 close to the display panel 1, the overall length of the flexible circuit board 2 and the printed circuit board 3 after the binding connection can be shortened in the first direction.

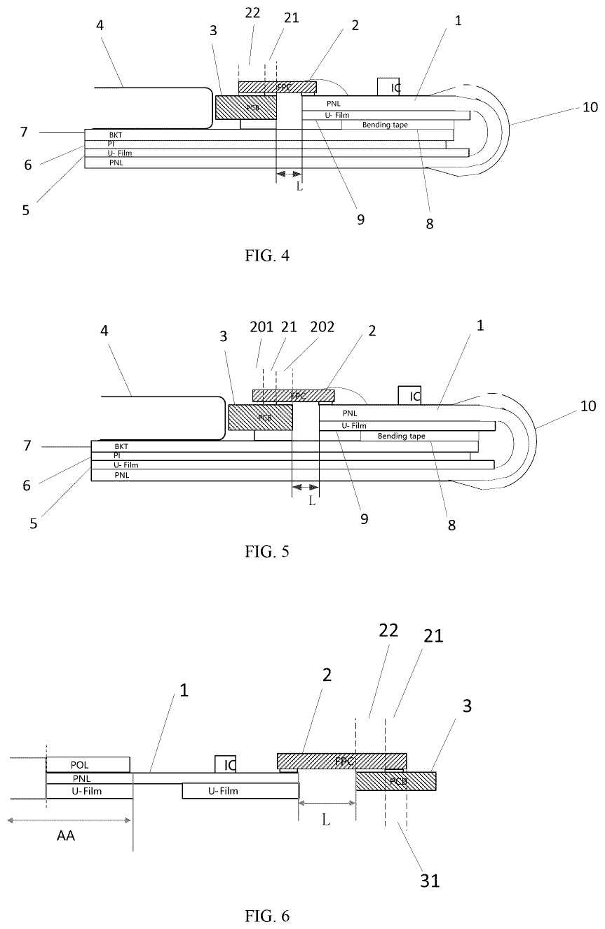

Referring to FIG. 4, in an exemplary embodiment, the first binding area 21 is located in the middle of the flexible circuit board 2, and the first area 22 is located on a side of the first binding area 21 away from the display panel 1.

Referring to FIG. 1, in order to shorten the total length of the flexible circuit board 2 and the printed circuit board 3 after the binding connection in the first direction, it is sufficient that the first binding area 21 is moved toward the side close to the display panel 1 in the first direction, and/or the second binding area 31 is moved away from the display panel 1, so as to increase the overlapping area of the flexible circuit board 2 and the printed circuit board 3 in the first direction.

Referring to FIG. 4, illustratively, the printed circuit board 3 is provided with a second binding area 31 for binding and connecting with the first binding area 21, and the second binding area 31 is located at an end of the printed circuit board 3 close to an end of the display panel 1.

Referring to FIG. 5, in an exemplary embodiment, in the first direction, the first binding area 21 is located in the middle of the flexible circuit board 2, and in the first direction, the first area 22 includes a first sub-area 201 located on a side of the first binding area 21 close to the display panel 1, and a second sub-area 202 located on a side of the first binding area 21 away from the display panel 1.

Compared with FIG. 1, in the first direction, the first binding area 21 is located in the middle of the flexible circuit board 2, and a first sub-area 201 and a second sub-area 202 are formed on opposite sides of the first binding area 21, respectively. At this time, at least part of the orthographic projection of the first sub-area 201 on the printed circuit board 3 is located outside the second binding area 31, and at least part of the orthographic projection of the second sub-area 202 on the printed circuit board 3 is located outside the second binding area 31. Thus, in the first direction, the overlapping area of the flexible circuit board 2 and the printed circuit board 3 is increased. and the total length of the bound and connected flexible circuit board 2 and the printed circuit board 3 is shortened.

It should be noted that, in an embodiment where the first binding area 21 is located in the middle of the flexible circuit board 2 and the first area 22 is located on the side of the first binding area 21 close to the display panel 1, the position of the second binding area 31 can be kept unchanged relative to the position of the second binding area 31 shown in FIG. 1, or the second binding area 31 can be moved a certain distance in the direction away from the display panel 1 relative to the position shown in FIG. 1 (not limited to setting the second binding area 31 in the middle of the printed circuit board 3) to further reduce the total length of the flexible circuit board 2 and the printed circuit board 3 after the binding connection.

Referring to FIG. 5, in an exemplary embodiment, a second binding area 31 for binding and connecting with the first binding area 21 is provided on the printed circuit board 3, and the second binding area 31 is located in the middle of the printed circuit board 3 in the first direction.

Exemplarily, in the first direction, a gap between the printed circuit board 3 and the display panel 1 is less than or equal to 1 mm.

The flexible circuit board 2 and the printed circuit board 3 adopt the binding connection method shown in FIG. 1, that is, the first binding area 21 is located at the edge of the flexible circuit board 2 on the side away from the display panel 1, and the second binding area 31 is located at the edge of the printed circuit board 3 on the side close to the display panel 1. The gap between the printed circuit board 3 and the display panel 1 in the first direction is greater than or equal to 6.15 mm. In this embodiment, in the first direction, the gap between the printed circuit board 3 and the display panel 1 is significantly reduced. For example, in the first direction, the gap between the printed circuit board 3 and the display panel 1 can be 0.8 mm, but it is not limited to this.

Exemplarily, the flexible circuit board 2 may be a single-layer board structure or a multi-layer board structure.

Exemplarily, the printed circuit board 3 may be a single-layer board structure or a multi-layer board structure.

Optionally in this embodiment, the flexible circuit board 2 is a multi-layer board structure, and/or the printed circuit board 3 is a multi-layer board structure.

Compared with a single-layer board structure, the flexible circuit board 2 is a multi-layer board structure, which can reduce the size of the flexible circuit board 2, and the printed circuit board 3 is a multi-layer board structure, which can reduce the size of the printed circuit board 3. Therefore, the flexible circuit board 2 is a multi-layer board structure, and/or the printed circuit board 3 is a multi-layer board structure, which cooperates with the formation of the first area 22. In the first direction, the total length of the flexible circuit board 2 and the printed circuit board 3 after the binding connection can be further shortened, and the wiring space of the flexible circuit board 2 and the printed circuit board 3 can be met.

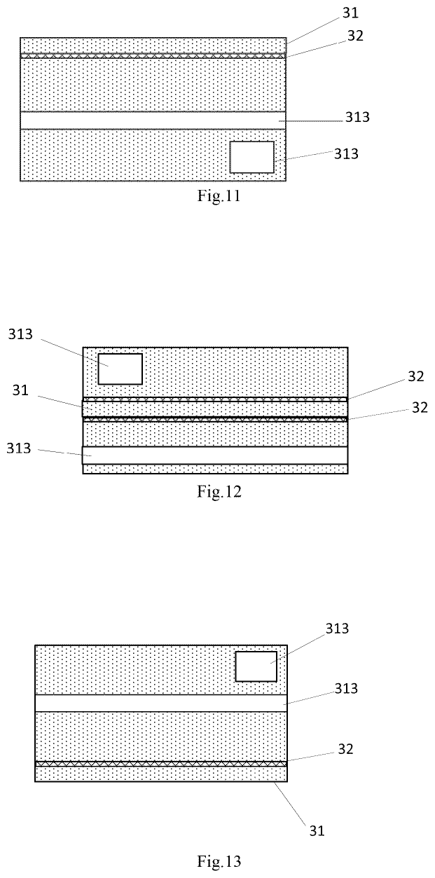

Referring to FIGS. 8 to 13, taking a printed circuit board 3 as an example, the printed circuit board 3 is a multi-layer board structure, including a substrate layer 311 and a multi-layer metal conductive layer 312 stacked on the substrate layer 311, and an insulating layer is provided between two adjacent metal conductive layers 312. In FIGS. 8, 10, 11 and 13, the printed circuit board 3 includes a main body area and the second binding area 31 located on one side of the main body area. In FIGS. 9 and 12, the printed circuit board 3 includes a main body area, and along the first direction, a hole is dug in the middle of the main body area to expose the corresponding metal conductive layer to form the second binding area 31. The main body area is also provided with components 313, and one of the multi-layer metal conductive layers 312 extends outward to form the second binding area 31.

The second binding area 31 includes a conductive pin and a green oil layer 32 located on a side of the conductive pin close to the main area. The green oil layer 32 can block water and oxygen and protect the conductive pin.

It should be noted that, when the second binding area 31 is located in the middle of the printed circuit board in the first direction, the green oil layer 32 is disposed on both opposite sides of the second binding area 31 in the first direction.

Exemplarily, the printed circuit board 3 includes a first side facing the flexible circuit board 2 and a second side away from the flexible circuit board 2, the second binding area 31 includes a gold finger, and the gold finger is located on the first side. A plurality of components 313 are arranged on the printed circuit board 3, and at least some of the components 313 are arranged on the second side, so as to ensure the accuracy of the binding connection between the printed circuit board 3 and the flexible circuit board 2 and increase the setting space of the components 313. In some embodiments, all the components 313 are arranged on the second side to avoid damage to the components caused by the binding connection between the printed circuit board 3 and the flexible circuit board 2.

Exemplarily, the component 313 is located in an area outside the second binding area 31 on the printed circuit board 3. In some embodiments, the printed circuit board 3 includes a second area corresponding to the first area (the orthographic projection of the first area on the printed circuit board 3 coincides with the second area), and the printed circuit board 3 includes a third area other than the second binding area 31 and the second area, and the component 313 is located in the third area. In this way, after the printed circuit board 3 and the flexible circuit board 2 are bound and connected, the component 313 is arranged on the printed circuit board 3 and the flexible circuit board 2, so that while ensuring the binding accuracy of the printed circuit board 3 and the flexible circuit board 2, the thickness of the display module in the light emitting direction of the display panel can be reduced (because if the component 313 is arranged in the overlapping area between the printed circuit board 3 and the flexible circuit board 2, when the printed circuit board 3 and the flexible circuit board 2 are bound and connected, the corresponding component 313 must be avoided, and the component 313 has a certain height, therefore, the distance between the printed circuit board 3 and the flexible circuit board 2 is limited).

Referring to FIGS. 8-10, exemplarily, when the printed circuit board 3 adopts a multi-layer board structure, it includes a component setting area 34, a lead setting area 33 and the second binding area 31, which are divided by dotted lines in FIG. 8. The component setting area 34 adopts a multi-layer board structure, the lead setting area 33 and the second binding area 31 are single-layer board structures, and the lead setting area 33 is provided with leads for connecting signals between the components of the component setting area 34 and the second binding area 31, which can reduce costs.

Exemplarily, the printed circuit board is a hard board with a certain rigidity, and the flexible circuit board is a flexible and foldable flexible board.

The embodiment of the present disclosure further provides a display device. comprising the above-mentioned display module.

The display module includes a display panel, a flexible circuit board and a printed circuit board, and the printed circuit board can provide a signal to the display panel through the flexible circuit board. The display panel also includes a driver IC, and under the control of the printed circuit board, the driver IC is configured to drive the display panel to display.

The display panel includes a non-bending area, a bendable area and a binding area, the binding area is configured to connect with the flexible circuit board, the bendable area is bent so that the binding area is bent to the backlight side of the display panel, and when the bendable area is in a bent state, a first back film layer 5, a PI layer 6, a supporting layer 7, a spacer layer 8 and a second back film layer 9 are stacked in sequence from the non-bending area to the binding area.

The support layer 7 can play a supporting role to maintain the flatness of the non-bending area of the display panel 1.

The spacer layer 8 can control the bending radius of the bendable area and enhance the reliability of the bending deformation of the bendable area.

Exemplarily, the printed circuit board 3 is connected to a side of the support layer 7 away from the non-bending area of the display panel 1 through an adhesive layer.

Exemplarily, along the first direction, the spacer layer 8 can extend away from the bendable area to form a first connecting portion, so that the printed circuit board 3 is connected to the first connecting portion, reducing the step difference between the binding area of the printed circuit board 3 and the display panel 1, and facilitating the binding connection between the flexible circuit board 2 and the printed circuit board 3.

Exemplarily, a buffer protection layer 10 is disposed on the outer side of the bendable area.

The display device may be any product or component with a display function, such as a liquid crystal television, a liquid crystal display, a digital photo frame, a mobile phone, a tablet computer, etc., the display device further includes a flexible circuit board, a printed circuit board and a backplane.

It is to be understood that the above embodiments are merely exemplary embodiments configured to illustrate the principles of the present disclosure, but the present disclosure is not limited thereto. For those of ordinary skill in the art, various modifications and improvements can be made without departing from the spirit and substance of the present disclosure, and these modifications and improvements are also considered to be within the scope of protection of the present disclosure.

1. A display module, comprising a display panel, a flexible circuit board and a printed circuit board, wherein along a first direction, the flexible circuit board is connected to an end of the display panel, and the flexible circuit board is bent to a backlight side of the display panel to be bound and connected with the printed circuit board, wherein:
the flexible circuit board comprises a first binding area for binding and connecting with the printed circuit board, and a first area adjacent to the first binding area in the first direction, an orthographic projection of the first area in a second direction is located on the printed circuit board, and the second direction is a direction perpendicular to a light emitting surface of the display panel.

2. The display module according to claim 1, wherein the first binding area is located at an end of the flexible circuit board away from the display panel, and the first area is located at a side of the first binding area close to the display panel.

3. The display module according to claim 2, wherein a second binding area for binding and connecting with the first binding area is provided on the printed circuit board, and in the first direction, the second binding area is located in a middle of the printed circuit board.

4. The display module according to claim 2, wherein a second binding area for binding and connecting with the first binding area is provided on the printed circuit board, and in the first direction, the second binding area is located at an end of the printed circuit board away from an end of the flexible circuit board.

5. The display module according to claim 1, wherein the first binding area is located in a middle of the flexible circuit board, and the first area is located at a side of the first binding area close to the display panel.

6. The display module according to claim 5, wherein a second binding area for binding and connecting with the first binding area is provided on the printed circuit board, and the second binding area is located at an end of the printed circuit board away from an end of the flexible circuit board.

7. The display module according to claim 1, wherein in the first direction, the first binding area is located in a middle of the flexible circuit board, and in the first direction, the first area comprises a first sub-area located on a side of the first binding area close to the display panel, and a second sub-area located on a side of the first binding area away from the display panel.

8. The display module according to claim 7, wherein a second binding area for binding and connecting with the first binding area is provided on the printed circuit board, and in the first direction, the second binding area is located in a middle of the printed circuit board.

9. The display module according to claim 1, wherein in the first direction, a gap between the printed circuit board and the display panel is less than or equal to 1 mm.

10. The display module according to claim 1, wherein at least one of the flexible circuit board and the printed circuit board is a multi-layer board structure.

11. The display module according to claim 10, wherein the printed circuit board is the multi-layer board structure, the printed circuit board comprises a main body area and a second binding area located at a side of the main body area; or, the printed circuit board comprises a main body area, and along the first direction, a hole is dug in the middle of the main body area to expose a corresponding metal conductive layer to form a second binding area, and the second binding area is for binding and connecting with the first binding area.

12. The display module according to claim 11, wherein the second binding area comprises a conductive pin and a green oil layer located on a side of the conductive pin close to the main area.

13. The display module according to claim 1, wherein the printed circuit board comprises a component setting area, a lead setting area and a second binding area, the second binding area is used for binding and connecting with the first binding area, and the lead setting area is provided with leads for signal connection between the components in the component setting area and the second binding area;
the component setting area is a multi-layer board structure, and the lead setting area and the second binding area are single-layer board structures.

14. A display device comprising a display module, wherein the display module comprises:
a display panel, a flexible circuit board and a printed circuit board, wherein along a first direction, the flexible circuit board is connected to an end of the display panel, and the flexible circuit board is bent to a backlight side of the display panel to be bound and connected with the printed circuit board, wherein:
the flexible circuit board comprises a first binding area for binding and connecting with the printed circuit board, and a first area adjacent to the first binding area in the first direction, an orthographic projection of the first area in a second direction is located on the printed circuit board. and the second direction is a direction perpendicular to a light emitting surface of the display panel.

15. The display device according to claim 14, wherein the first binding area is located at an end of the flexible circuit board away from the display panel, and the first area is located at a side of the first binding area close to the display panel.

16. The display device according to claim 15, wherein a second binding area for binding and connecting with the first binding area is provided on the printed circuit board, and in the first direction, the second binding area is located in a middle of the printed circuit board.

17. The display device according to claim 15, wherein a second binding area for binding and connecting with the first binding area is provided on the printed circuit board, and in the first direction, the second binding area is located at an end of the printed circuit board away from an end of the flexible circuit board.

18. The display device according to claim 14, wherein the first binding area is located in a middle of the flexible circuit board, and the first area is located at a side of the first binding area close to the display panel.

19. The display device according to claim 18, wherein a second binding area for binding and connecting with the first binding area is provided on the printed circuit board, and the second binding area is located at an end of the printed circuit board away from an end of the flexible circuit board.

20. The display device according to claim 14, wherein in the first direction, the first binding area is located in a middle of the flexible circuit board, and in the first direction, the first area comprises a first sub-area located on a side of the first binding area close to the display panel, and a second sub-area located on a side of the first binding area away from the display panel.
